(19) United States
(12) Patent Application Publication
(10) Pub. No.: US 2024/0162038 A1
(43) Pub. Date: May 16, 2024

(54) PHOTOMASK STRUCTURE, SEMICONDUCTOR STRUCTURE AND MANUFACTURING METHOD THEREOF

(71) Applicant: United Microelectronics Corp., Hsinchu (TW)

(72) Inventors: Chien Heng Liu, Pingtung County (TW); Chia-Wei Huang, Kaohsiung City (TW); Yung-Feng Cheng, Kaohsiung City (TW); Ming-Jui Chen, Hsinchu City (TW)

(73) Assignee: United Microelectronics Corp., Hsinchu (TW)

(21) Appl. No.: 18/167,093

(22) Filed: Feb. 10, 2023

(30) Foreign Application Priority Data
Nov. 14, 2022 (CN) 202211419165.3

(51) Int. Cl. H01L 21/027; G03F 1/76

(52) U.S. Cl. CPC H01L 21/0271; G03F 1/76

(57) ABSTRACT

A photomask structure including a first layout pattern and a second layout pattern is provided. The second layout pattern is located on one side of the first layout pattern. The first layout pattern and the second layout pattern are separated from each other. The first layout pattern has a first edge and a second edge opposite to each other. The second layout pattern has a third edge and a fourth edge opposite to each other. The third edge of the second layout pattern is adjacent to the first edge of the first layout pattern. The second layout pattern includes a first extension portion exceeding an end of the first layout pattern. The first extension portion includes a first protruding portion protruding from the third edge of the second layout pattern. The first protruding portion exceeds the first edge of the first layout pattern.

### CROSS-REFERENCE TO RELATED APPLICATION

This application claims the priority benefit of China application serial no. 202211419165.3, filed on Nov. 14, 2022. The entirety of the above-mentioned patent application is hereby incorporated by reference herein and made a part of this specification.

### BACKGROUND

### Technical Field

The invention relates to a photomask structure, a semiconductor structure and a manufacturing method thereof, and particularly relates to a photomask structure, a semiconductor structure and a manufacturing method thereof which can improve the process window of the semiconductor process.

### Description of Related Art

In the semiconductor process, the lithography technology plays an important role. However, the photoresist pattern formed by the lithography process often suffers from the problem of deformation (e.g., necking, line end shortening, or line end shrinkage). Therefore, how to develop a photomask that can prevent the deformation of the photoresist pattern formed by the lithography process is the goal of continuous efforts.

### SUMMARY

The invention provides a photomask structure, which can prevent the problem of the deformation of the photoresist pattern formed by the lithography process, thereby improving the process window of the semiconductor process.

The invention provides a semiconductor structure and a manufacturing method thereof, which can prevent the problem of the deformation of the pattern in the semiconductor structure, thereby improving the process window of the semiconductor process.

The invention provides a photomask structure, which includes a first layout pattern and a second layout pattern. The second layout pattern is located on one side of the first layout pattern. The first layout pattern and the second layout pattern are separated from each other. The first layout pattern has a first edge and a second edge opposite to each other. The second layout pattern has a third edge and a fourth edge opposite to each other. The third edge of the second layout pattern is adjacent to the first edge of the first layout pattern. The second layout pattern includes a first extension portion exceeding an end of the first layout pattern. The first extension portion includes a first protruding portion protruding from the third edge of the second layout pattern. The first protruding portion exceeds the first edge of the first layout pattern.

According to an embodiment of the invention, in the photomask structure, the first protruding portion may have a fifth edge, and the fifth edge of the first protruding portion may be away from the third edge of the second layout pattern.

According to an embodiment of the invention, in the photomask structure, the fifth edge of the first protruding portion may be flush with the second edge of the first layout pattern.

According to an embodiment of the invention, the photomask structure may further include a third layout pattern. The third layout pattern is located on the other side of the first layout pattern.

According to an embodiment of the invention, in the photomask structure, the first layout pattern, the second layout pattern, and the third layout pattern may be separated from each other.

According to an embodiment of the invention, in the photomask structure, the spacing between the first protruding portion and the third layout pattern may be greater than or equal to the minimum spacing specified by the design rule.

According to an embodiment of the invention, in the photomask structure, the spacing between the first protruding portion and the first layout pattern may be greater than or equal to the minimum spacing specified by the design rule.

According to an embodiment of the invention, in the photomask structure, the first protruding portion may further exceed the second edge of the first layout pattern.

The invention provides a manufacturing method of a semiconductor structure, which includes the following steps. A substrate is provided. A material layer is formed on the substrate. A patterned photoresist layer is formed on the material layer by performing a lithography process through the above photomask structure. The material layer is patterned by using the patterned photoresist layer as a mask to form a first pattern and a second pattern. The second pattern is located on one side of the first pattern. The first pattern and the second pattern are separated from each other. The first pattern has a fifth edge and a sixth edge opposite to each other. The second pattern has a seventh edge and a eighth edge opposite to each other. The seventh edge of the second pattern is adjacent to the fifth edge of the first pattern. The second pattern includes a second extension portion exceeding an end of the first pattern. The second extension portion includes a second protruding portion protruding from the seventh edge of the second pattern. The second protruding portion exceeds the fifth edge of the first pattern.

According to an embodiment of the invention, in the manufacturing method of the semiconductor structure, the second protruding portion may have a ninth edge, and the ninth edge of the second protruding portion may be away from the seventh edge of the second pattern.

According to an embodiment of the invention, in the manufacturing method of the semiconductor structure, the ninth edge of the second protruding portion may be flush with the sixth edge of the first pattern.

According to an embodiment of the invention, in the manufacturing method of the semiconductor structure, the step of patterning the material layer by using the patterned photoresist layer as a mask may further form a third pattern. The third pattern is located on the other side of the first pattern.

According to an embodiment of the invention, in the manufacturing method of the semiconductor structure, the first pattern, the second pattern, and the third pattern may be separated from each other.

According to an embodiment of the invention, in the manufacturing method of the semiconductor structure, the second protruding portion may further exceed the sixth edge of the first pattern.

The invention provides a semiconductor structure, which includes a substrate and a material layer. The material layer is located on the substrate. The material layer includes a first pattern and a second pattern. The second pattern is located on one side of the first pattern. The first pattern and the second pattern are separated from each other. The first pattern has a first edge and a second edge opposite to each other. The second pattern has a third edge and a fourth edge opposite to each other. The third edge of the second pattern is adjacent to the first edge of the first pattern. The second pattern includes an extension portion exceeding an end of the first pattern. The extension portion includes a protruding portion protruding from the third edge of the second pattern. The protruding portion exceeds the first edge of the first pattern.

According to an embodiment of the invention, in the semiconductor structure, the protruding portion may have a fifth edge, and the fifth edge of the protruding portion may be away from the third edge of the second pattern.

According to an embodiment of the invention, in the semiconductor structure, the fifth edge of the protruding portion may be flush with the second edge of the first pattern.

According to an embodiment of the invention, in the semiconductor structure, the material layer may further include a third pattern. The third pattern is located on the other side of the first pattern.

According to an embodiment of the invention, in the semiconductor structure, the first pattern, the second pattern, and the third pattern may be separated from each other.

According to an embodiment of the invention, in the semiconductor structure, the protruding portion may further exceed the second edge of the first pattern.

Based on the above description, the photomask structure according to the invention includes the first layout pattern and the second layout pattern. The first layout pattern has a first edge and a second edge opposite to each other. The second layout pattern has a third edge and a fourth edge opposite to each other. The third edge of the second layout pattern is adjacent to the first edge of the first layout pattern. The second layout pattern includes a first extension portion exceeding an end of the first layout pattern. The first extension portion includes a first protruding portion protruding from the third edge of the second layout pattern. The first protruding portion exceeds the first edge of the first layout pattern. Therefore, when the lithography process is performed by using the photomask structure according to the invention, the pattern fidelity of the lithography process can be improved. In this way, when the lithography process is performed by using the photomask structure according to the invention, the problem of deformation (e.g., necking, line end shortening, or line end shrinkage) of the photoresist pattern formed by the lithography process and corresponding to the layout pattern (e.g., first layout pattern and/or second layout pattern) can be effectively prevented, and the process window of the semiconductor process can be improved.

In addition, the semiconductor structure and the manufacturing method thereof according to the invention can prevent the problem of the deformation (e.g., necking, line end shortening, or line end shrinkage) of the pattern (e.g., first pattern and/or second pattern) in the semiconductor structure, thereby improving the process window of the semiconductor process. In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic top view illustrating a photomask structure according to some embodiments of the invention.

FIG. 1B is a schematic top view illustrating a photomask structure according to other embodiments of the invention.

FIG. 1C is a schematic top view illustrating a photomask structure according to other embodiments of the invention.

FIG. 2A to FIG. 2D are schematic top views illustrating a manufacturing process of a semiconductor structure according to some embodiments of the invention.

FIG. 2E is a schematic top view illustrating a semiconductor structure according to other embodiments of the invention.

FIG. 2F is a schematic top view illustrating a semiconductor structure according to other embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. In fact, the dimensions of the various features may be arbitrarily increased or reduced for clarity of discussion.

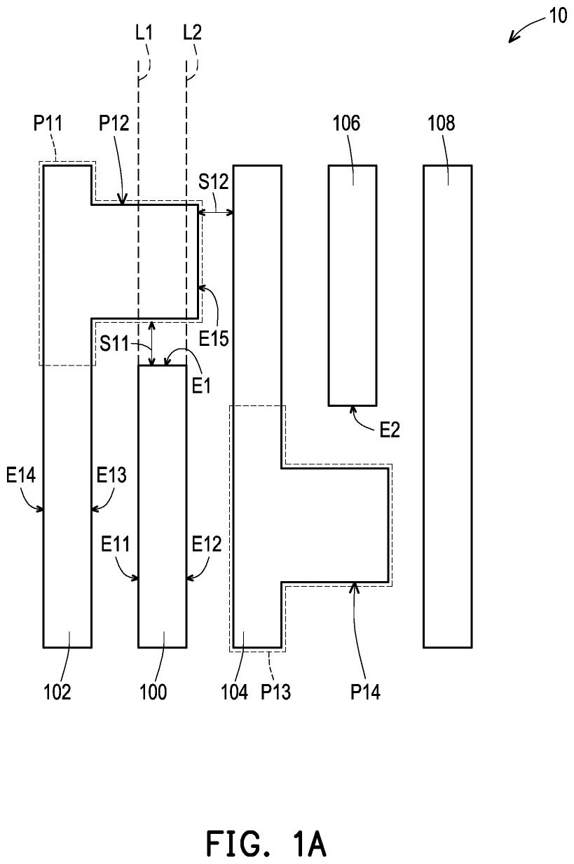

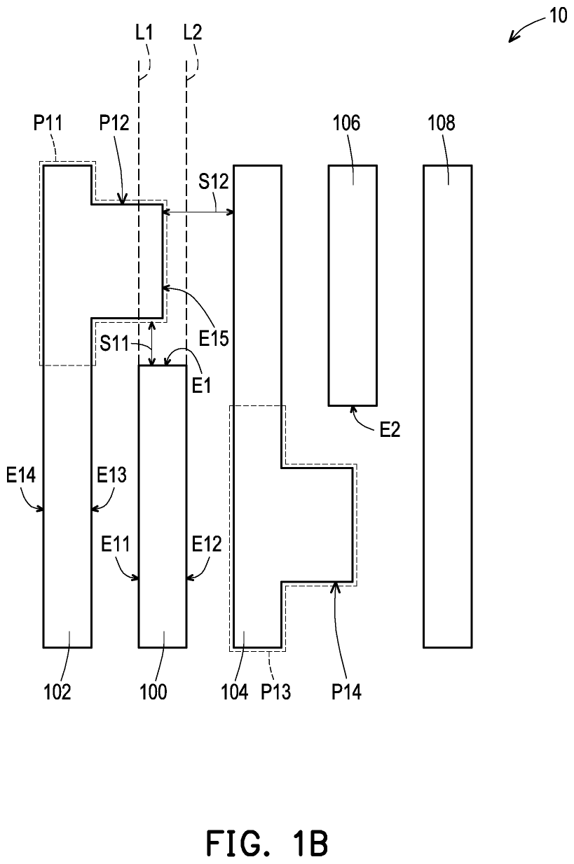

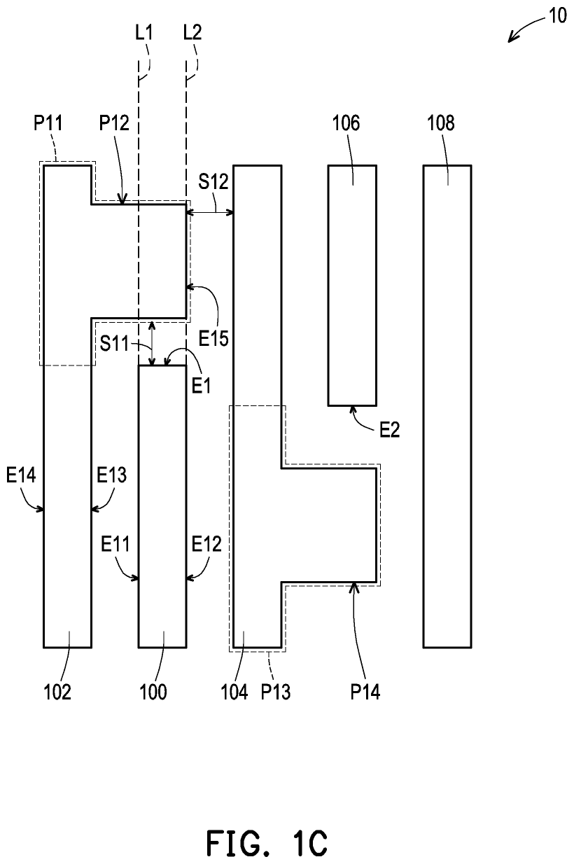

FIG. 1A is a schematic top view illustrating a photomask structure according to some embodiments of the invention. FIG. 1B is a schematic top view illustrating a photomask structure according to other embodiments of the invention. FIG. 1C is a schematic top view illustrating a photomask structure according to other embodiments of the invention.

Referring to FIG. 1A, a photomask structure 10 includes a layout pattern 100 and a layout pattern 102. In some embodiments, the photomask structure 10 can be a binary mask or a phase shift mask (PSM), but the invention is not limited thereto.

The layout pattern 102 is located on one side of the layout pattern 100. The layout pattern 100 and the layout pattern 102 are separated from each other. The layout pattern 100 has an edge E11 and an edge E12 opposite to each other. The layout pattern 102 has an edge E13 and an edge E14 opposite to each other. The edge E13 of the layout pattern 102 is adjacent to the edge E11 of the layout pattern 100.

The layout pattern 102 includes an extension portion P11 exceeding an end E1 of the layout pattern 100. The extension portion P11 includes a protruding portion P12 protruding from the edge E13 of the layout pattern 102. The spacing S11 between the protruding portion P12 and the layout pattern 100 may be greater than or equal to the minimum spacing specified by the design rule. The protruding portion P12 may have an edge E15, and the edge E15 of the protruding portion P12 may be away from the edge E13 of the layout pattern 102.

The protruding portion P12 exceeds the edge E11 of the layout pattern 100. That is, the protruding portion P12 may pass through the imaginary extension line L1 of the edge E11 of the layout pattern 100. In the present embodiment, the protruding portion P12 may further exceed the edge E12 of the layout pattern 100. That is, the protruding portion P12 may pass through the imaginary extension line L2 of the edge E12 of the layout pattern 100, but the invention is not limited thereto. As long as the protruding portion P12 exceeds the edge E11 of the layout pattern 100, it falls within the scope of the invention.

In other embodiments, as shown in FIG. 1B, the protruding portion P12 exceeds the edge E11 of the layout pattern 100, but the protruding portion P12 does not exceed the edge E12 of the layout pattern 100. That is, as shown in FIG. 1B, the protruding portion P12 may pass through the imaginary extension line L1 of the edge E11 of the layout pattern 100, but the protruding portion P12 does not pass through the imaginary extension line L2 of the edge E12 of the layout pattern 100. In FIG. 1B, the edge E15 of the protruding portion P12 may be located between the imaginary extension line L1 and the imaginary extension line L2. In addition, in FIG. 1A and FIG. 1B, the same or similar components are denoted by the same reference symbols, and the description thereof is omitted.

In other embodiments, as shown in FIG. 1C, the protruding portion P12 exceeds the edge E11 of the layout pattern 100, and the edge E15 of the protruding portion P12 may be flush with the edge E12 of the layout pattern 100. That is, as shown in FIG. 1C, the protruding portion P12 may pass through the imaginary extension line L1 of the edge E11 of the layout pattern 100, and the edge E15 of the protruding portion P12 may overlap the imaginary extension line L2 of the edge E12 of the layout pattern 100. In addition, in FIG. 1A and FIG. 1C, the same or similar components are denoted by the same reference symbols, and the description thereof is omitted.

In some embodiments, the photomask structure 10 may further include a layout pattern 104. The layout pattern 104 is located on the other side of the layout pattern 100. The layout pattern 100, the layout pattern 102, and the layout pattern 104 may be separated from each other. The spacing S12 between the protruding portion P12 and the layout pattern 104 may be greater than or equal to the minimum spacing specified by the design rule.

In some embodiments, the photomask structure 10 may further include at least one of a layout pattern 106 and a layout pattern 108. The layout pattern 106 is located between the layout pattern 104 and the layout pattern 108. The layout pattern 100, the layout pattern 102, the layout pattern 104, the layout pattern 106, and the layout pattern 108 may be separated from each other. In the present embodiment, since the layout pattern 104 and the layout pattern 108 exceed an end E2 of the layout pattern 106, the layout pattern 104 or the layout pattern 108 may be designed in the same manner as the layout pattern 102. For example, after the layout pattern 104 is designed in the same manner as the layout pattern 102, the layout pattern 104 may include an extension portion P13 exceeding the end E2 of the layout pattern 106, and the extension portion P13 may be designed to have a protruding portion P14. In addition, the design method of the protruding portion P14 may refer to the design method of the protruding portion P12, and the description thereof is not repeated here.

In some embodiments, when the photomask structure 10 is a binary mask, the layout pattern 100, the layout pattern 102, the layout pattern 104, the layout pattern 106, and the layout pattern 108 may be light-transmitting patterns on the binary mask. In other embodiments, when the photomask structure 10 is a binary mask, the layout pattern 100, the layout pattern 102, the layout pattern 104, the layout pattern 106, and the layout pattern 108 may be opaque patterns on the binary mask. In other embodiments, when the photomask structure 10 is a phase shift mask, the layout pattern 100, the layout pattern 102, the layout pattern 104, the layout pattern 106, and the layout pattern 108 may be light-transmitting patterns on the phase shift mask. In other embodiments, when the photomask structure 10 is a phase shift mask, the layout pattern 100, the layout pattern 102, the layout pattern 104, the layout pattern 106, and the layout pattern 108 may be phase shift patterns on the phase shift mask.

Based on the above embodiments, the photomask structure 10 includes the layout pattern 100 and the layout pattern 102. The layout pattern 100 has the edge E11 and the edge E12 opposite to each other. The layout pattern 102 has the edge E13 and the edge E14 opposite to each other. The edge E13 of the layout pattern 102 is adjacent to the edge E11 of the layout pattern 100. The layout pattern 102 includes the extension portion P11 exceeding the end E1 of the layout pattern 100. The extension portion P11 includes the protruding portion P12 protruding from the edge E13 of the layout pattern 102. The protruding portion P12 exceeds the edge E11 of the layout pattern 100. Therefore, when the lithography process is performed by using the photomask structure 10, the pattern fidelity of the lithography process can be improved. In this way, when the lithography process is performed by using the photomask structure 10, the problem of deformation (e.g., necking, line end shortening, or line end shrinkage) of the photoresist pattern formed by the lithography process and corresponding to the layout pattern (e.g., layout pattern 100 and/or second layout pattern 102) can be effectively prevented, and the process window of the semiconductor process can be improved.

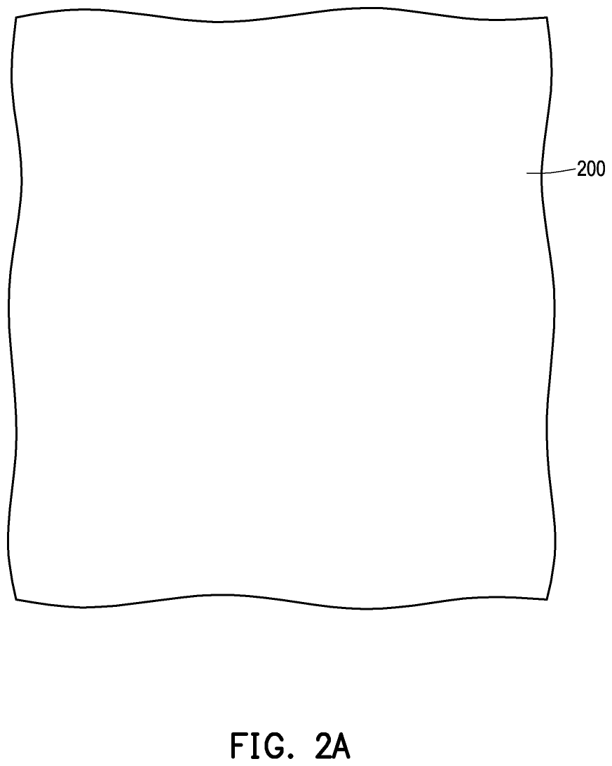

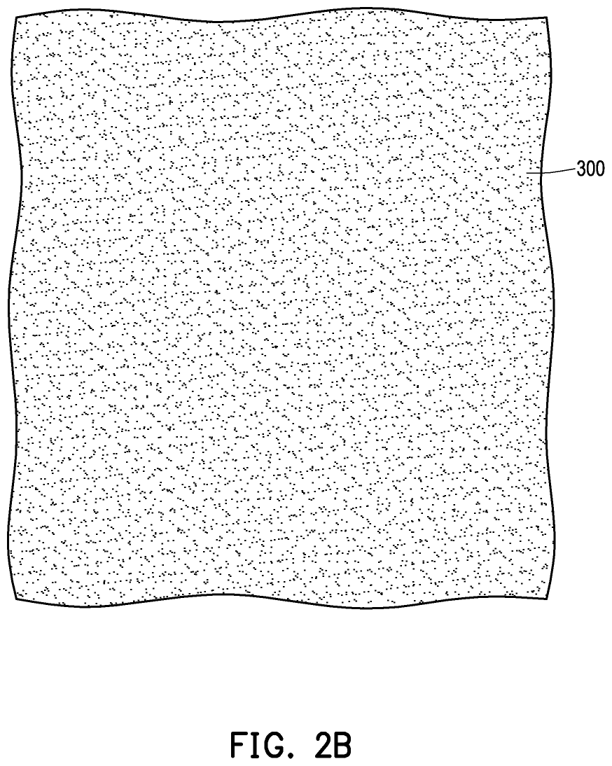

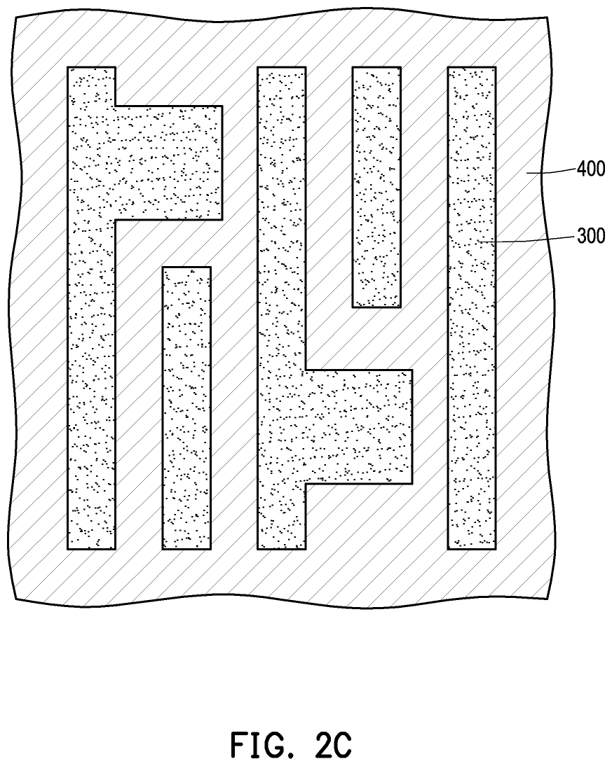

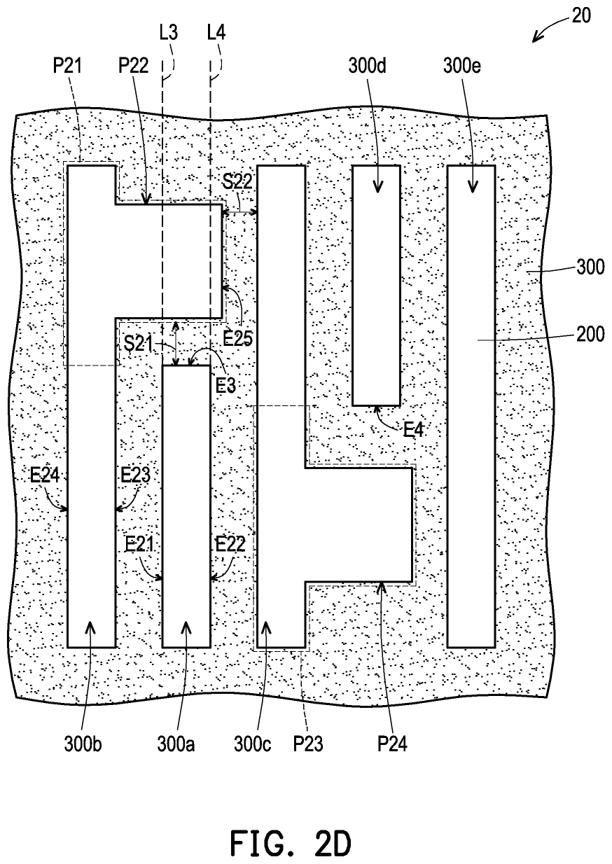

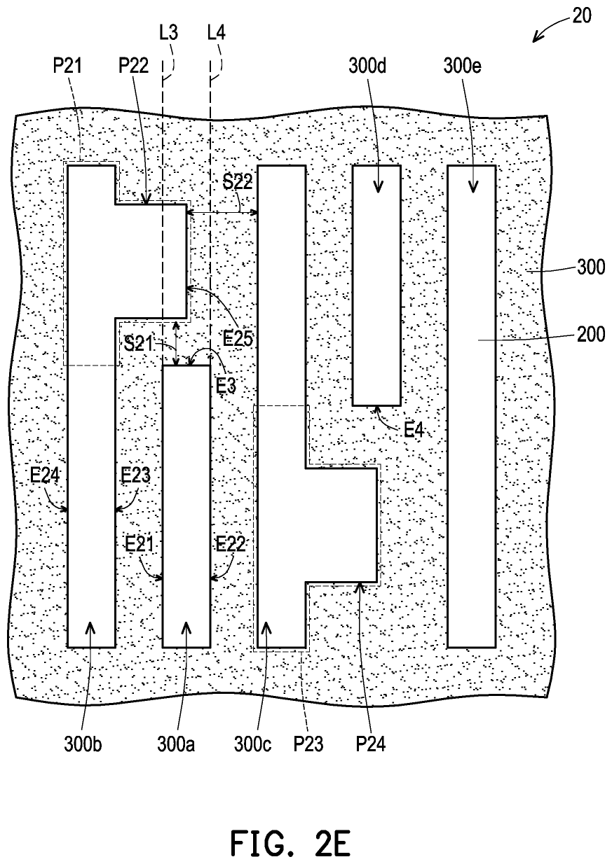

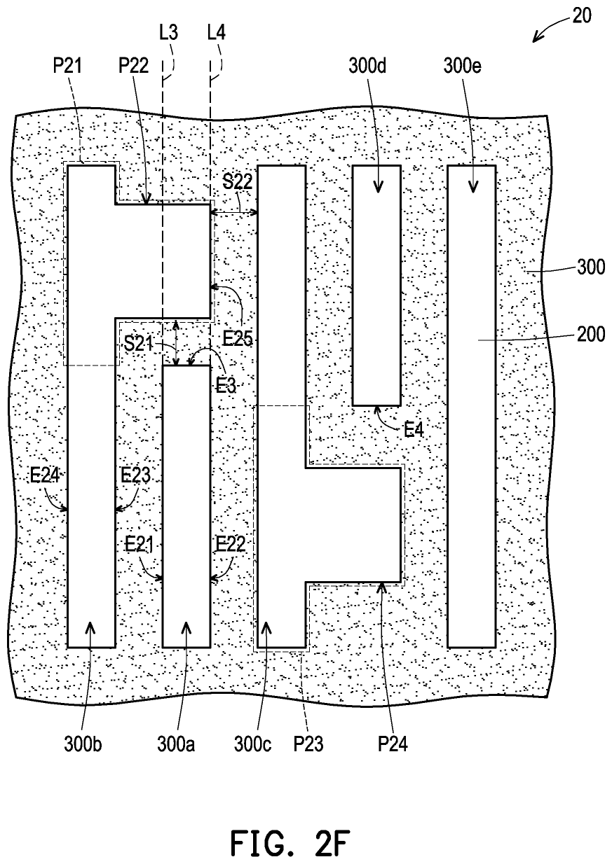

FIG. 2A to FIG. 2D are schematic top views illustrating a manufacturing process of a semiconductor structure according to some embodiments of the invention. FIG. 2E is a schematic top view illustrating a semiconductor structure according to other embodiments of the invention. FIG. 2F is a schematic top view illustrating a semiconductor structure according to other embodiments of the invention.

Referring to FIG. 2A, a substrate 200 is provided. The substrate 200 may be a semiconductor substrate such as a silicon substrate, but the invention is not limited thereto. In some embodiments, the required components (e.g., active device, passive device, dielectric layer and/or interconnect structure) (not shown) may be formed in and/or on the substrate 200 according to the product requirement, and the description thereof is omitted here.

Referring to FIG. 2B, a material layer 300 is formed on the substrate 200. The material of the material layer 300 is, for example, a dielectric material, a conductive material, or a semiconductor material. The method of forming the material layer 300 is, for example, a chemical vapor deposition (CVD) method or a physical vapor deposition (PVD) method, but the invention is not limited thereto.

Referring to FIG. 2C, a patterned photoresist layer 400 is formed on the material layer 300 by performing a lithography process through the photomask structure 10 in FIG. 1A. The patterned photoresist layer 400 may expose a portion of the material layer 300.

Referring to FIG. 2D, the material layer 300 is patterned by using the patterned photoresist layer 400 as a mask to form a pattern 300a and a pattern 300b. In some embodiments, the step of patterning the material layer 300 by using the patterned photoresist layer 400 as a mask may further form at least one of a pattern 300c, a pattern 300d, and a pattern 300e. The pattern 300a, the pattern 300b, the pattern 300c, the pattern 300d, and the pattern 300e in material layer 300 may correspond to the layout pattern 100, the layout pattern 102, the layout pattern 104, the layout pattern 106, and the layout pattern 108 in the photomask structure 10, respectively. In some embodiments, the material layer 300 may be patterned by removing a portion of the material layer 300 by using the patterned photoresist layer 400 as a mask. A method of removing the portion of the material layer 300 is, for example, a dry etching method. Then, the patterned photoresist layer 400 may be removed. The method of removing the patterned photoresist layer 400 is, for example, a dry stripping method or a wet stripping method.

In some embodiments, the layout pattern 100, the layout pattern 102, the layout pattern 104, the layout pattern 106, and the layout pattern 108 of the photomask structure 10 may be light-transmitting patterns, the material of the patterned photoresist layer 400 may be a positive photoresist material, and the pattern 300a, the pattern 300b, the pattern 300c, the pattern 300d, and the pattern 300e formed by the above method may be openings exposing the substrate 200.

In other embodiments, the layout pattern 100, the layout pattern 102, the layout pattern 104, the layout pattern 106, and the layout pattern 108 of the photomask structure 10 may be opaque patterns or phase shift patterns, the material of the patterned photoresist layer 400 may be a negative photoresist material, and the pattern 300a, the pattern 300b, the pattern 300c, the pattern 300d, and the pattern 300e formed by the above method may be openings exposing the substrate 200.

In the present embodiment, the pattern 300a, the pattern 300b, the pattern 300c, the pattern 300d, and the pattern 300e are, for example, openings, but the invention is not limited thereto. In other embodiments, by adjusting the types (e.g., light-transmitting patterns, opaque patterns or phase shift patterns) of the layout pattern 100, the layout pattern 102, the layout pattern 104, the layout pattern 106, and the layout pattern 108 and adjusting the material (e.g., positive photoresist material or negative photoresist material) of the patterned photoresist layer 400, the physical patterns (e.g., conductive lines) corresponding to the layout pattern 100, the layout pattern 102, the layout pattern 104, the layout pattern 106, and the layout pattern 108 in the photomask structure 10 may be formed on the substrate 200 by the above method, and the description thereof is omitted here. That is, in other embodiments, the pattern 300a, the pattern 300b, the pattern 300c, the pattern 300d, and the pattern 300e may be physical patterns (e.g., conductive lines) located on the substrate 200 and covering a portion of the substrate 200.

In the present embodiment, the semiconductor structure 20 in FIG. 2D may be formed by using the photomask structure 10 in FIG. 1A and the above method. In other embodiments, the semiconductor structure 20 in FIG. 2E may be formed by using the photomask structure 10 in FIG. 1B and the above method. In other embodiments, the semiconductor structure 20 in FIG. 2F may be formed by using the photomask structure 10 in FIG. 1C and the above method.

Hereinafter, the semiconductor structure 20 of the present embodiment will be described with reference to FIG. 2D. In addition, although the method for forming the semiconductor structure 20 is described by taking the above method as an example, the invention is not limited thereto.

Referring to FIG. 2D, the semiconductor structure 20 includes a substrate 200 and a material layer 300. The material layer 300 is located on the substrate 200. The material layer 300 includes a pattern 300a and a pattern 300b. The pattern 300b is located on one side of the pattern 300a. The pattern 300a and the pattern 300b are separated from each other. The pattern 300a has an edge E21 and an edge E22 opposite to each other. The pattern 300b has an edge E23 and an edge E24 opposite to each other. The edge E23 of the pattern 300b is adjacent to the edge E21 of the pattern 300a.

The pattern 300b includes an extension portion P21 exceeding an end E3 of the pattern 300a. The extension portion P21 includes a protruding portion P22 protruding from the edge E23 of the pattern 300b. The spacing S21 between the protruding portion P22 and the pattern 300a may be greater than or equal to the minimum spacing specified by the design rule. The protruding portion P22 may have an edge E25, and the edge E25 of the protruding portion P22 may be away from the edge E23 of the pattern 300b.

The protruding portion P22 exceeds the edge E21 of the pattern 300a. That is, the protruding portion P22 may pass through the imaginary extension line L3 of the edge E21 of the pattern 300a. In the present embodiment, the protruding portion P22 may further exceed the edge E22 of the pattern 300a. That is, the protruding portion P22 may pass through the imaginary extension line L4 of the edge E22 of the pattern 300a, but the invention is not limited thereto. As long as the protruding portion P22 exceeds the edge E21 of the pattern 300a, it falls within the scope of the invention.

In other embodiments, as shown in FIG. 2E, the protruding portion P22 exceeds the edge E21 of the pattern 300a, but the protruding portion P22 does not exceed the edge E22 of the pattern 300a. That is, as shown in FIG. 2E, the protruding portion P22 may pass through the imaginary extension line L3 of the edge E21 of the pattern 300a, but the protruding portion P22 does not pass through the imaginary extension line L4 of the edge E22 of the pattern 300a. In FIG. 2E, the edge E25 of the protruding portion P22 may be located between the imaginary extension line L3 and the imaginary extension line L4. In addition, in FIG. 2D and FIG. 2E, the same or similar components are denoted by the same reference symbols, and the description thereof is omitted.

In other embodiments, as shown in FIG. 2F, the protruding portion P22 exceeds the edge E21 of the pattern 300a, and the edge E25 of the protruding portion P22 may be flush with the edge E22 of the pattern 300a. That is, as shown in FIG. 2F, the protruding portion P22 may pass through the imaginary extension line L3 of the edge E21 of the pattern 300a, and the edge E25 of the protruding portion P22 may overlap the imaginary extension line L4 of the edge E22 of the pattern 300a. In addition, in FIG. 2D and FIG. 2F, the same or similar components are denoted by the same reference symbols, and the description thereof is omitted.

In some embodiments, the material layer 300 may further include a pattern 300c. the pattern 300c is located on the other side of the pattern 300a. The pattern 300a, the pattern 300b, and the pattern 300c may be separated from each other. The spacing S22 between the protruding portion P22 and the pattern 300c may be greater than or equal to the minimum spacing specified by the design rule.

In some embodiments, the material layer 300 may further include at least one of a pattern 300d and a pattern 300e. The pattern 300d is located between the pattern 300c and the pattern 300e. The pattern 300a, the pattern 300b, the pattern 300c, the pattern 300d, and the pattern 300e may be separated from each other. In the present embodiment, since the pattern 300c and the pattern 300e exceed an end E4 of the pattern 300d, the pattern 300c or the pattern 300e may be designed in the same manner as the pattern 300b. For example, after the pattern 300c is designed in the same manner as the layout pattern 300b, the pattern 300c may include an extension portion P23 exceeding the end E4 of the pattern 300d, and the extension portion P23 may be designed to have a protruding portion P24. In addition, the design method of the protruding portion P24 may refer to the design method of the protruding portion P22, and the description thereof is not repeated here.

In the present embodiment, the pattern 300a, the pattern 300b, the pattern 300c, the pattern 300d, and the pattern 300e are, for example, openings exposing the substrate 200, but the invention is not limited thereto. In other embodiments, the pattern 300a, the pattern 300b, the pattern 300c, the pattern 300d, and the pattern 300e may be physical patterns (e.g., conductive lines) located on the substrate 200 and covering a portion of the substrate 200, and the description thereof is omitted here.

Based on the above embodiments, the semiconductor structure 20 and the manufacturing method thereof can prevent the problem of the deformation (e.g., necking, line end shortening, or line end shrinkage) of the pattern (e.g., pattern 300a and/or pattern 300b) in the semiconductor structure 20, thereby improving the process window of the semiconductor process.

In summary, the photomask structure of the aforementioned embodiments can prevent the problem of the deformation of the photoresist pattern formed by the lithography process, thereby improving the process window of the semiconductor process. In addition, the semiconductor structure and the manufacturing method thereof of the aforementioned embodiments can prevent the problem of the deformation (e.g., necking, line end shortening, or line end shrinkage) of the pattern in the semiconductor structure, thereby improving the process window of the semiconductor process.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A photomask structure, comprising:
a first layout pattern; and
a second layout pattern located on one side of the first layout pattern, wherein
the first layout pattern and the second layout pattern are separated from each other,
the first layout pattern has a first edge and a second edge opposite to each other,
the second layout pattern has a third edge and a fourth edge opposite to each other,
the third edge of the second layout pattern is adjacent to the first edge of the first layout pattern,
the second layout pattern comprises a first extension portion exceeding an end of the first layout pattern,
the first extension portion comprises a first protruding portion protruding from the third edge of the second layout pattern, and
the first protruding portion exceeds the first edge of the first layout pattern.

2. The photomask structure according to claim 1, wherein the first protruding portion has a fifth edge, and the fifth edge of the first protruding portion is away from the third edge of the second layout pattern.

3. The photomask structure according to claim 2, wherein the fifth edge of the first protruding portion is flush with the second edge of the first layout pattern.

4. The photomask structure according to claim 1, further comprising:
a third layout pattern located on the other side of the first layout pattern.

5. The photomask structure according to claim 4, wherein the first layout pattern, the second layout pattern, and the third layout pattern are separated from each other.

6. The photomask structure according to claim 4, wherein a spacing between the first protruding portion and the third layout pattern is greater than or equal to a minimum spacing specified by a design rule.

7. The photomask structure according to claim 1, wherein a spacing between the first protruding portion and the first layout pattern is greater than or equal to a minimum spacing specified by a design rule.

8. The photomask structure according to claim 1, wherein the first protruding portion further exceeds the second edge of the first layout pattern.

9. A manufacturing method of a semiconductor structure, comprising:
providing a substrate;
forming a material layer on the substrate;
forming a patterned photoresist layer on the material layer by performing a lithography process through the photomask structure according to claim 1; and
patterning the material layer by using the patterned photoresist layer as a mask to form a first pattern and a second pattern, wherein
the second pattern is located on one side of the first pattern,
the first pattern and the second pattern are separated from each other,
the first pattern has a fifth edge and a sixth edge opposite to each other,
the second pattern has a seventh edge and a eighth edge opposite to each other,
the seventh edge of the second pattern is adjacent to the fifth edge of the first pattern,
the second pattern comprises a second extension portion exceeding an end of the first pattern,
the second extension portion comprises a second protruding portion protruding from the seventh edge of the second pattern, and
the second protruding portion exceeds the fifth edge of the first pattern.

10. The manufacturing method of the semiconductor structure according to claim 9, wherein the second protruding portion has a ninth edge, and the ninth edge of the second protruding portion is away from the seventh edge of the second pattern.

11. The manufacturing method of the semiconductor structure according to claim 10, wherein the ninth edge of the second protruding portion is flush with the sixth edge of the first pattern.

12. The manufacturing method of the semiconductor structure according to claim 9, wherein the step of patterning the material layer by using the patterned photoresist layer as a mask further forms a third pattern, and the third pattern is located on the other side of the first pattern.

13. The manufacturing method of the semiconductor structure according to claim 12, wherein the first pattern, the second pattern, and the third pattern are separated from each other.

14. The manufacturing method of the semiconductor structure according to claim 9, wherein the second protruding portion further exceeds the sixth edge of the first pattern.

15. A semiconductor structure, comprising:
a substrate; and
a material layer located on the substrate and comprising a first pattern and a second pattern, wherein
the second pattern is located on one side of the first pattern,
the first pattern and the second pattern are separated from each other,
the first pattern has a first edge and a second edge opposite to each other,
the second pattern has a third edge and a fourth edge opposite to each other,
the third edge of the second pattern is adjacent to the first edge of the first pattern,
the second pattern comprises an extension portion exceeding an end of the first pattern,
the extension portion comprises a protruding portion protruding from the third edge of the second pattern, and
the protruding portion exceeds the first edge of the first pattern.

16. The semiconductor structure according to claim 15, wherein the protruding portion has a fifth edge, and the fifth edge of the protruding portion is away from the third edge of the second pattern.

17. The semiconductor structure according to claim 16, wherein the fifth edge of the protruding portion is flush with the second edge of the first pattern.

18. The semiconductor structure according to claim 15, wherein the material layer further comprises:
a third pattern located on the other side of the first pattern.

19. The semiconductor structure according to claim 18, wherein the first pattern, the second pattern, and the third pattern are separated from each other.

20. The semiconductor structure according to claim 15, wherein the protruding portion further exceeds the second edge of the first pattern.
